(19) United States
(12) Patent Application Publication
(10) Pub. No.: US 2015/0097611 A1
(43) Pub. Date: Apr. 9, 2015

(54) VOLTAGE FOLLOWER HAVING A FEED-FORWARD DEVICE

(71) Applicant: LSI Corporation, San Jose, CA (US)

(72) Inventor: Ryutaro Saito, Tokyo (JP)

(73) Assignee: LSI Corporation, San Jose, CA (US)

(21) Appl. No.: 14/044,988

(22) Filed: Oct. 3, 2013

(51) Int. Cl. H03K 5/01; H03F 3/45

(52) U.S. Cl. CPC H03K 5/01; H03F 3/45071; H03F 2200/153; H03F 2203/45116
USPC 327/323

(57) ABSTRACT

A circuit is described that includes a voltage follower device and a feed-forward device. In an implementation, the circuit includes a voltage follower device that includes an input and an output. The voltage follower device is configured to transfer a voltage signal at least substantially unchanged from the input to the output of the voltage follower device. The circuit also includes a feed-forward device that includes an input and an output. The input of the feed-forward device is connected to the input of the voltage follower device and the output of the feed-forward device is connected to the output of the voltage follower device. The feed-forward device is configured to output the voltage signal to the output of the voltage follower device.

### FIELD OF THE INVENTION

The present invention is directed to a voltage follower device, and more particularly to a voltage follower having a feed forward device.

### BACKGROUND

Voltage followers are amplifiers that employ feedback to allow an output voltage signal to follow an input voltage signal. In other words, the voltage follower transfers the input voltage signal ideally unchanged. Voltage followers are typically utilized to eliminate loading effects by connecting a device with a high source impedance to a device with a low input impedance.

### SUMMARY

A circuit is described that includes a voltage follower device and a feed-forward device. In an implementation, the circuit includes a voltage follower device that includes an input and an output. The voltage follower device is configured to transfer a voltage signal at least substantially unchanged from the input to the output of the voltage follower device. The circuit also includes a feed-forward device that includes an input and an output. The input of the feed-forward device is connected to the input of the voltage follower device and the output of the feed-forward device is connected to the output of the voltage follower device. The feed-forward device is configured to output the voltage signal to the output of the voltage follower device.

This Summary is provided to introduce a selection of concepts in a simplified form that are further described below in the Written Description. This Summary is not intended to identify key features or essential features of the claimed subject matter, nor is it intended to be used as an aid in determining the scope of the claimed subject matter.

### BRIEF DESCRIPTION OF THE FIGURES

The Written Description is described with reference to the accompanying figures. The use of the same reference numbers in different instances in the description and the figures may indicate similar or identical items.

FIG. 1 is a block diagram of a voltage follower in accordance with an example embodiment of the present disclosure.

FIG. 2 is a circuit diagram illustrating the voltage follower shown in FIG. 1 in accordance with an example embodiment of the present disclosure.

FIG. 3 is a circuit diagram illustrating a voltage follower in accordance with another example embodiment of the present disclosure.

FIG. 4 is a system that includes a controller operatively connected to a memory system in accordance with an example embodiment of the present disclosure, where the controller includes a voltage follower shown in FIGS. 1 and 2.

FIG. 5 is an example graph illustrating a settling time signal associated with the voltage follower shown in FIGS. 1 and 2 compared with a settling time signal associated with a typical voltage follower.

FIG. 6 is an example graph illustrating an output drivability signal associated with the voltage follower shown in FIGS. 1 and 2 compared with an output drivability signal associated with a typical voltage follower.

### WRITTEN DESCRIPTION

Two important characteristics of voltage followers are settling time (e.g., amount of time for which an output signal has entered and remained within a specified error band) and output drivability (e.g., driving an output signal at lower load resistances). Voltage followers processed utilizing Bi-CMOS fabrication techniques may improve settling time and output drivability; however, Bi-CMOS remains an expensive process as compared to CMOS fabrication techniques.

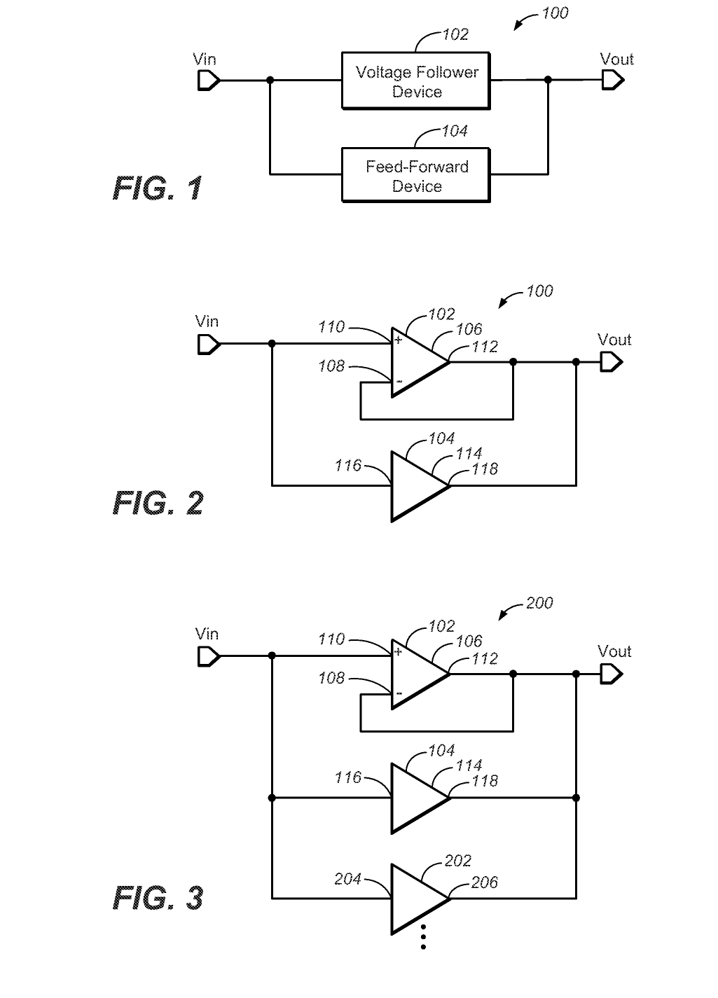

FIG. 1 is a block diagram illustrating a voltage follower 100 in accordance with an example embodiment of the present disclosure. As shown, the voltage follower 100 includes a voltage follower device 102 and a feed-forward device 104, which is connected in parallel with the voltage follower device 102. The feed-forward device 104 is utilized to improve settling time and output drivability (e.g., drive an output signal at a lower load resistance) of the voltage follower 100 as compared to voltage follower circuits not including a feed-forward device 104 in accordance with the present disclosure, as described herein. A voltage follower 100, or a unity gain buffer, is utilized to transfer a voltage signal at least substantially unchanged (e.g., ideal voltage gain A_{V} of 1, or 0 dB) from an input source to an output source. Voltage followers can reduce loading effects due to the output voltage following (e.g., tracking) the input voltage.

As shown in FIG. 2, the voltage follower device 102 comprises a first amplifier 106 that furnishes voltage follower functionality. The first amplifier 106 includes an inverting terminal 108, a non-inverting terminal 110, and an output terminal 112. The non-inverting terminal 110 is connected to a signal source (Vin) and the inverting terminal 108 is connected to the output terminal 112. The first amplifier 106 is configured to output a voltage signal furnished to the amplifier 106 to the output terminal 112 at least substantially unchanged.

As shown in FIG. 2, the feed-forward device 104 comprises a second amplifier 114 that is connected between the signal source and the output terminal 112. The second amplifier 114 is utilized to furnish feed-forward functionality to the voltage follower 100 (e.g., to assist in removing loop compensation capacitance). For example, the second amplifier 114 provides the input voltage signal to the output terminal 112 to reduce settling time of the output signal from the first amplifier 106 at the output terminal 112 and to improve output drivability without affecting closed loop stability. In situations when the output voltage signal at the output terminal 112 is at least substantially settled, the feed-forward characteristics of the second amplifier 114 do not at least substantially affect the voltage buffer (e.g., voltage follower) characteristics of the first amplifier 106. The second amplifier 114 includes an input terminal 116 and an output terminal 118. The input terminal 116 is connected to the signal source (Vin). As shown, the input terminal 116 of the second amplifier 114 is connected to the non-inverting terminal 110 of the first amplifier 106 and the output terminal 120 of the second amplifier 114 is connected to the output terminal 112 of the first amplifier 106. In one or more embodiments of the present disclosure, the first amplifier 106 and the second amplifier 114 comprise operational amplifiers. In a specific embodiment of the present disclosure, the first amplifier 106 and the second amplifier 114 are fabricated utilizing suitable complementary metal-oxide-semiconductor (CMOS) techniques. For example, the amplifiers 106, 114 are constructed of multiple metal-oxide-semiconductor field-effect transistor (MOSFET) devices. Generally, the second amplifier 114 is a replica circuit of the first amplifier 106. For example, the second amplifier 114 employs the same number of transistor devices arranged in the same configuration as the first amplifier 106.

FIG. 3 illustrates an example voltage follower 200 according to another implementation of the present disclosure. As shown, the voltage follower 200 may include a first amplifier 106, a second amplifier 114, and a third amplifier 202. The second amplifier 114 and the third amplifier 202 are configured to furnish feed-forward functionality to the voltage follower 200. It is understood that while only two feed-forward devices (e.g., the second amplifier 114 and the third amplifier 202) are illustrated, any number of feed-forward devices may be utilized according to the requirements of the system utilizing the voltage follower to improve start-up time and/or drivability of the system. As shown, the third amplifier 202 includes an input terminal 204 and an output terminal 206. The input terminal 204 is connected to the signal source (Vin). As shown, the input terminal 204 of the third amplifier 202 is connected to the non-inverting terminal 110 of the first amplifier 106 and the output terminal 206 of the second amplifier 202 is connected to the output terminal 112 of the first amplifier 106. The input terminal 204 of the third amplifier 202 is also connected to the input terminal 116 of the second amplifier 114 and the output terminal 206 of the third amplifier 202 is connected to the output terminal 118 of the second amplifier 114.

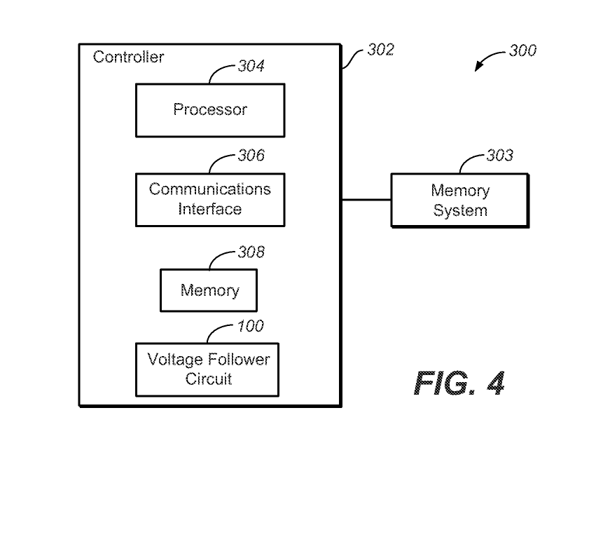

FIG. 4 illustrates an example system 300 that includes a controller 302 that includes the voltage follower 100. In one or more embodiments of the present disclosure, the controller 302 is utilized to control a memory system 303. For example, the memory system 203 may comprise a cache memory system, a hard disk drive (HDD) system, a redundant array of independent disks (RAID) system, or the like. The voltage follower 100 can be utilized within the controller 302 to furnish a voltage follower signal (e.g., output signal) at a reduced settling time as compared to typical voltage follower devices. The voltage follower 100 can also drive the output signal at a lower load resistance as compared to typical voltage follower devices.

A controller 302, including some or all of its components, can operate under computer control. For example, a processor 304 can be included with or in a controller 302 to control the components and functions of systems 200 described herein using software, firmware, hardware (e.g., fixed logic circuitry), manual processing, or a combination thereof. The terms “controller,” “functionality,” “service,” and “logic” as used herein generally represent software, firmware, hardware, or a combination of software, firmware, or hardware in conjunction with controlling the systems 200. In the case of a software implementation, the module, functionality, or logic represents program code that performs specified tasks when executed on a processor (e.g., central processing unit (CPU) or CPUs). The program code can be stored in one or more computer-readable memory devices (e.g., internal memory and/or one or more tangible media), and so on. The structures, functions, approaches, and techniques described herein can be implemented on a variety of commercial computing platforms having a variety of processors.

A processor 304 provides processing functionality for the controller 302 and can include any number of processors, micro-controllers, or other processing systems, and resident or external memory for storing data and other information accessed or generated by the system 200. The processor 304 can execute one or more software programs that implement techniques described herein. The processor 304 is not limited by the materials from which it is formed or the processing mechanisms employed therein and, as such, can be implemented via semiconductor(s) and/or transistors (e.g., using electronic integrated circuit (IC) components), and so forth.

The controller 302 includes a communications interface 306. The communications interface 306 is operatively configured to communicate with components of the system 200. For example, the communications interface 306 can be configured to transmit data for storage in the system 200, retrieve data from storage in the system 200, and so forth. The communications interface 306 is also communicatively coupled with the processor 304 to facilitate data transfer between components of the system 200 and the processor 304 (e.g., for communicating inputs to the processor 304 received from a device communicatively coupled with the system 200). It should be noted that while the communications interface 306 is described as a component of a system 200, one or more components of the communications interface 306 can be implemented as external components communicatively coupled to the system 200 via a wired and/or wireless connection.

The communications interface 306 and/or the processor 304 can be configured to communicate with a variety of different networks including, but not necessarily limited to: a wide-area cellular telephone network, such as a 3G cellular network, a 4G cellular network, or a global system for mobile communications (GSM) network; a wireless computer communications network, such as a WiFi network (e.g., a wireless local area network (WLAN) operated using IEEE 802.11 network standards); an internet; the Internet; a wide area network (WAN); a local area network (LAN); a personal area network (PAN) (e.g., a wireless personal area network (WPAN) operated using IEEE 802.15 network standards); a public telephone network; an extranet; an intranet; and so on. However, this list is provided by way of example only and is not meant to be restrictive of the present disclosure. Further, the communications interface 306 can be configured to communicate with a single network or multiple networks across different access points.

The controller 302 also includes a memory 308. The memory 308 is an example of tangible, computer-readable storage medium that provides storage functionality to store various data associated with operation of the controller 302, such as software programs and/or code segments, or other data to instruct the processor 304, and possibly other components of the controller 302, to perform the functionality described herein. Thus, the memory 308 can store data, such as a program of instructions for operating the controller 302 (including its components), and so forth. It should be noted that while a single memory 308 is described, a wide variety of types and combinations of memory (e.g., tangible, non-transitory memory) can be employed. The memory 308 can be integral with the processor 304, can comprise stand-alone memory, or can be a combination of both. The memory 308 can include, but is not necessarily limited to: removable and non-removable memory components, such as random-access memory (RAM), read-only memory (ROM), flash memory (e.g., a secure digital (SD) memory card, a mini-SD memory card, and/or a micro-SD memory card), magnetic memory, optical memory, universal serial bus (USB) memory devices, hard disk memory, external memory, and so forth.

While FIG. 4 illustrates that the voltage follower 100 can be employed by a controller, it is understood that the voltage follower 100 can be employed by other integrated circuit devices to furnish output signals having reduced settling times and greater output drivability. For example, the voltage follower 100 may be employed within HDD systems, preamplifier circuits, power management devices, and the like.

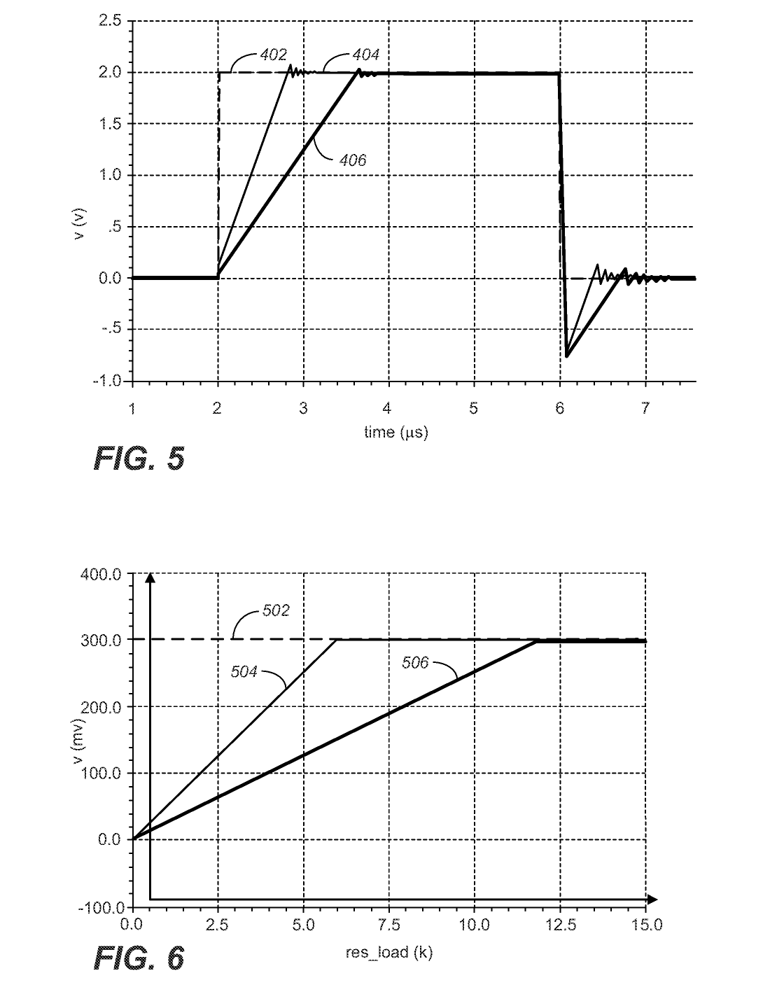

FIGS. 5 and 6 illustrate example graphs illustrating the settling time and the output drivability, respectively, of the voltage follower 100 as compared to a typical voltage follower. FIG. 5 illustrates an input signal 402, a settling time signal 404 associated with the circuitry of the voltage follower 100, and a settling time signal 406 associated with the circuitry (e.g., a single voltage follower amplifier architecture) of a typical voltage follower device. FIG. 6 illustrates an input signal 502, an output signal 504 associated with the circuitry of the voltage follower 100, and an output signal 506 associated with the circuitry (e.g., a single voltage follower amplifier architecture) of a typical voltage follower device. Specifically, FIG. 6 illustrates that the voltage follower 100 can drive an output signal at a lower load resistance as compared to a typical voltage follower device

Generally, any of the functions described herein can be implemented using hardware (e.g., fixed logic circuitry such as integrated circuits), software, firmware, manual processing, or a combination thereof. Thus, the blocks discussed in the above disclosure generally represent hardware (e.g., fixed logic circuitry such as integrated circuits), software, firmware, or a combination thereof. In embodiments of the disclosure that manifest in the form of integrated circuits, the various blocks discussed in the above disclosure can be implemented as integrated circuits along with other functionality. Such integrated circuits can include all of the functions of a given block, system, or circuit, or a portion of the functions of the block, system or circuit. Further, elements of the blocks, systems, or circuits can be implemented across multiple integrated circuits. Such integrated circuits can comprise various integrated circuits including, but not necessarily limited to: a system on a chip (SoC), a monolithic integrated circuit, a flip chip integrated circuit, a multichip module integrated circuit, and/or a mixed signal integrated circuit. In embodiments of the disclosure that manifest in the form of software, the various blocks discussed in the above disclosure represent executable instructions (e.g., program code) that perform specified tasks when executed on a processor. These executable instructions can be stored in one or more tangible computer readable media. In some such embodiments, the entire system, block or circuit can be implemented using its software or firmware equivalent. In some embodiments, one part of a given system, block or circuit can be implemented in software or firmware, while other parts are implemented in hardware.

Although embodiments of the disclosure have been described in language specific to structural features and/or methodological acts, it is to be understood that the subject matter defined in the appended claims is not necessarily limited to the specific embodiments described. Although various configurations are discussed, the apparatus, systems, subsystems, components and so forth can be constructed in a variety of ways without departing from teachings of this disclosure. Rather, the specific features and acts are disclosed as embodiments of implementing the claims.

What is claimed is:

1. A circuit comprising:
a voltage follower device including a voltage follower device input and a voltage follower device output, the voltage follower device configured to transfer a voltage signal at least substantially unchanged from the voltage follower device input to the voltage follower device output; and
a feed-forward device including a feed-forward device input and a feed-forward device output, the feed-forward device input electrically connected to the voltage follower device input and the feed-forward device output electrically connected to the voltage follower device output, the feed-forward device configured to output the voltage signal to the voltage follower device output.

2. The circuit as recited in claim 1, wherein the feed-forward device is a replica of the voltage follower device.

3. The circuit as recited in claim 1, wherein the voltage follower device comprises a first amplifier and the feed-forward device comprises a second amplifier.

4. The circuit as recited in claim 3, wherein the first amplifier comprises an operational amplifier and the second amplifier comprises an operational amplifier.

5. The circuit as recited in claim 1, wherein the voltage follower device includes a plurality of metal-oxide-semiconductor field-effect transistor (MOSFET) devices.

6. The circuit as recited in claim 1, wherein the feed-forward device is configured to reduce a settling time associated with the voltage follower device.

7. The circuit as recited in claim 1, wherein the feed-forward device is configured to drive the voltage signal at the voltage follower output at a lower load resistance.

8. A voltage follower comprising:
a first amplifier including an input terminal and an output terminal, the first amplifier configured to transfer a voltage signal at least substantially unchanged from the input terminal to the output terminal; and
a second amplifier including an input terminal and an output terminal, the input terminal of the second amplifier electrically connected to the input terminal of the first amplifier, the output terminal of the second amplifier electrically connected to the output terminal of the first amplifier, the second amplifier configured to output the voltage signal to the output terminal of the first amplifier to at least partially reduce a settling time associated with the first amplifier.

9. The voltage follower device as recited in claim 7, wherein the second amplifier is a replica amplifier device of the second amplifier.

10. The voltage follower device as recited in claim 7, wherein the first amplifier comprises an operational amplifier and the second amplifier comprises an operational amplifier.

11. The voltage follower device as recited in claim 7, further comprising a third amplifier including an input terminal and an output terminal, the input terminal of the second amplifier electrically connected to the input terminal of the third amplifier, the output terminal of the third amplifier electrically connected to the output terminal of the first amplifier, the third amplifier configured to output the voltage signal to the output terminal of the first amplifier to at least partially reduce a settling time associated with the first amplifier.

12. The voltage follower device as recited in claim 7, wherein the feed-forward device is configured to reduce a settling time associated with the voltage follower device.

13. The voltage follower device as recited in claim 7, wherein the second amplifier is configured to drive the voltage signal at the voltage follower output at a lower load resistance.

14. A system comprising:
a controller configured to operatively couple to a memory system, the controller including:
a voltage follower device including a voltage follower device input and a voltage follower device output, the voltage follower configured to transfer a voltage signal at least substantially unchanged from the input to the output; and
a feed-forward device including a feed-forward device input and a feed-forward device output, the feed-forward device input electrically connected to the voltage follower device input and the feed-forward device output electrically connected to the voltage follower device output, the feed-forward device configured to output the voltage signal to the voltage follower device output.

15. The system as recited in claim 14, wherein the feed-forward device is a replica of the voltage follower device.

16. The system as recited in claim 14, wherein the voltage follower device comprises a first amplifier and the feed-forward device comprises a second amplifier.

17. The system as recited in claim 16, wherein the first amplifier comprises an operational amplifier and the second amplifier comprises an operational amplifier.

18. The system as recited in claim 13, wherein the voltage follower device includes a plurality of metal-oxide-semiconductor field-effect transistor (MOSFET) devices.

19. The system as recited in claim 13, wherein the feed-forward device is configured to reduce a settling time associated with the voltage follower device.

20. The system as recited in claim 13, wherein the feed-forward device is configured to drive the voltage signal at the voltage follower output at a lower load resistance.
